(19) United States
(12) Patent Application Publication
(10) Pub. No.: US 2008/0245543 A1
(43) Pub. Date: Oct. 9, 2008

(54) MONOLITHIC INTEGRATED CIRCUIT ARRANGEMENT

(76) Inventors: Samir El Rai, Colorado Springs, CO (US); Ralf Tempel, Duisburg (DE)

Correspondence Address: Muncy, Geissler, Olds & Lowe, PLLC, P.O. BOX 1364, FAIRFAX, VA, 22038-1364, US

(21) Appl. No.: 12/107,057

(22) Filed: Apr. 21, 2008

Related U.S. Application Data
(63) Continuation of application No. PCT/EP2006/009937, filed on Oct. 14, 2006.

(30) Foreign Application Priority Data
Oct. 21, 2005 (DE) 10 2005 050 484.1

(51) Int. Cl. H05K 9/00

(52) U.S. Cl. 174/32

(57) ABSTRACT

A monolithic integrated circuit arrangement is provided that includes a first circuit component, which is formed as a differentially supplied coil and has at least one conductor loop encompassing an interior region, and at least one additional circuit component. According to an embodiment of the invention, the additional circuit component of the circuit arrangement is disposed in the interior region.

This nonprovisional application is a continuation of International Application No. PCT/EP2006/009937, which was filed on Oct. 14, 2006, and which claims priority to German Patent Application No. DE 10 2005 050 484.1, which was filed in Germany on Oct. 21, 2005, and which are both herein incorporated by reference.

### BACKGROUND OF THE INVENTION

1. Field of the Invention

The present invention relates to a monolithic integrated circuit arrangement comprising a first circuit component, which is formed as a differentially supplied coil and has at least one conductor loop encompassing an interior region, and at least one additional circuit component.

2. Description of the Background Art

Such circuit arrangements are known and used, for example, for building tank circuits for voltage-controlled oscillators (VCO) and other circuits requiring inductive elements.

A particular disadvantage of such circuit arrangements is the poor integratability of coils into the monolithic integrated circuits, particularly because of the relatively large area requirement of the coil itself and the minimum distances to be maintained to the neighboring circuit components, particularly to keep electromagnetic interactions low and thereby to avoid interferences.

### SUMMARY OF THE INVENTION

It is therefore an object of the present invention to improve a circuit arrangement with respect to its area requirement.

This object is attained according to the invention in the case of the aforementioned circuit arrangement in that the additional circuit component of the circuit arrangement is disposed in the interior region.

An area requirement of the entire circuit arrangement can be reduced by the arrangement of the invention of at least one additional circuit component of the circuit arrangement according to the invention in the interior region of the coil. Furthermore, suitable lines or connecting lines between the coil and the additional circuit component disposed in the interior region can be designed especially short, so that parasitic effects typically caused by lines, such as ohmic losses or capacitive effects, can be reduced.

Tests performed by the applicant have shown that in the case of a differential supplying of the coil the resulting magnetic field in the interior of the coil concentrates primarily around a conductor forming the conductor loop and declines considerably toward the interior of the coil, so that this interior region can be used for the arrangement of additional circuit components, without disrupting the operation of the coil or without interference with the coil's magnetic field.

In an embodiment of the present invention, the additional circuit component has one or more passive elements, particularly capacitive elements. The arrangement of capacitive elements according to the invention within the interior region of the coil advantageously enables the configuration of monolithic integrated LC combinations, as they are often necessary in resonant circuits, filters, and other circuits. The total area requirement of the LC combinations of the invention is considerably lower than that of conventional circuit arrangements in which the capacitive elements are not disposed in the interior region of the coil but outside the coil. Additional advantages result at the same time because of the reduced line length according to the invention, such as, e.g., an improved quality due to the lower ohmic losses and increased accuracy with respect to a resonance frequency due to the lower parasitic capacitances in the lines.

The capacitive elements in another embodiment of the present invention are formed especially advantageously as a configurable capacitor matrix (CDAC), in which a plurality of individual capacitors can be connected to one another in various ways and thereby enable the setting of different resulting substitute capacitances. Formation of the capacitive elements as capacitance diodes is also possible. Furthermore, the additional circuit component according to the invention may also have a combination of one or more capacitors and a capacitance diode.

Moreover, in the case of the circuit arrangement of the invention, it is also conceivable to dispose resistive elements, such as e.g., ohmic resistors, in the interior region of the coil.

According to another embodiment of the present invention, active elements, particularly transistors, can also be provided very advantageously in the additional circuit component, which is disposed according to the invention in the interior region of the coil.

In another embodiment of the present invention, different conductor sections of the coil, particularly different conductor loops of the coil, are disposed in different metallization levels of a substrate accommodating the circuit arrangement. Particularly with a design of the coil as a multi-turn coil, the use of different metallization levels is very expedient, because the area requirement of the coil can be kept low in this way.

Another embodiment of the present invention is characterized in that a shielding device, which extends at least partially between at least one conductor loop of the coil and the additional circuit component, is disposed in the interior region of the conductor loop. The shielding device is used to reduce further the electrical or magnetic field strength in the interior region of the coil and can be associated, for example, with a ground potential of the circuit arrangement of the invention.

Another embodiment of the present invention is characterized in that the coil has at least one pair of legs each symmetric to one another. This type of symmetric design of the coil assures especially low magnetic field strengths in the interior region of the coil in regard to the differential supplying of the coil.

Another embodiment of the invention provides especially advantageously that the additional circuit component and/or the control lines assigned to the additional circuit component are disposed in the area of an axis of symmetry of the coil, said axis running between the legs. The arrangement of the aforementioned components in the area of the axis of symmetry assures minimum electromagnetic interaction between the magnetic field of the coil and the components disposed in its interior region.

Areas extending outside the coil along the axis of symmetry also have an especially low magnetic field strength, so that circuit components, control lines, and the like can be advantageously disposed in these regions as well.

A monolithic integrated circuit with at least one circuit arrangement of the invention is provided as another means for attaining the object of the present invention.

An embodiment of the circuit of the invention is characterized by at least two metallization levels.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a first embodiment of the circuit arrangement of the invention in a plan view,

FIG. 2 shows a second embodiment of the circuit arrangement of the invention,

FIG. 3 shows a third embodiment of the circuit arrangement of the invention,

FIG. 4 shows a fourth embodiment of the circuit arrangement of the invention,

FIG. 5 shows an embodiment of the circuit arrangement of the invention with a coil having two turns, and

FIG. 6 shows another embodiment of the circuit arrangement of the invention with a coil having two turns.

### DETAILED DESCRIPTION

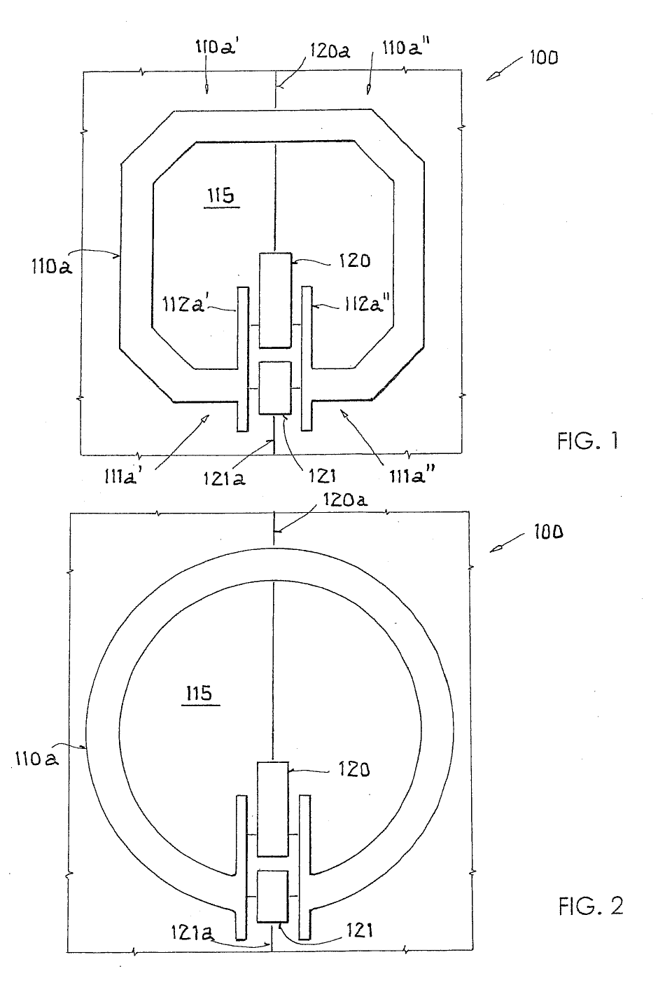

FIG. 1 shows a first embodiment of the monolithic integrated circuit arrangement 100 of the invention, which has a first circuit component formed as a differentially supplied coil. The coil is substantially formed by a conductor loop 110a, which is divided into legs 110a′, 110a″ symmetric to one another. Furthermore, the coil has terminals 111a′, 111a″ at which it is supplied with a differential signal.

The differential supplying of the coil in the present example occurs via an additional circuit component 121, which has an active element and is connected to terminals 111a′, 111a″ of the coil in each case by connecting lines, which are not indicated in greater detail.

Moreover, circuit arrangement 100 of the invention has yet another circuit component 120, which preferably has passive elements, particularly capacitive elements, and which is likewise connected to terminals 111a′, 111a″ of the coil via corresponding lines 112a′, 112a″.

The circuit shown in FIG. 1 can be, for example, a voltage-controlled oscillator (VCO), in which the coil of the invention together with the capacitive elements of additional circuit component 120 forms a tank circuit, which is supplied with power by the active elements of additional circuit component 121. The active elements of additional circuit component 121 are accordingly supplied with control signals via control line 121a of a control circuit, which is not shown.

The arrangement of additional components 120, 121 according to the invention in an interior region 115, not used in conventional circuit arrangements, within conductor loop 110a of the coil of the invention enables the configuration of circuit arrangement 100 with a minimum area requirement.

Preferably, additional circuit component 120 and a control line 120a assigned to it are arranged along an axis of symmetry (not shown) between the two legs 110a′, 110a″ of the coil, because especially low magnetic field strengths result in this region during operation of circuit arrangement 100 shown in FIG. 1. Control line 120a in the present example extends directly on the axis of symmetry.

The capacitive elements of additional circuit component 120 according to FIG. 1 are formed, for example, as a configurable capacitor matrix, which depending on a control signal supplied by control line 120a can be connected to one another in different ways and thereby enable matching of the resonance frequency of the tank circuit formed by the coil and the capacitive elements.

The arrangement of additional circuit component 120 in interior region 115 of the coil, as taught by the invention, furthermore produces very advantageously an especially short length for lines 112a′, 112a″ that connect the coil or its terminals 111a′, 111a″ to the capacitive elements of additional circuit component 120, as a result of which relatively low ohmic losses arise in lines 112a′, 112a″ in comparison with conventional circuit arrangements.

Reduction of ohmic losses in lines 112a′, 112a″ in this way is very expedient particularly during the configuration of the circuit arrangement as an LC resonant circuit, because in the case of resonance especially large currents flow through the particular elements and lines 112a′, 112a″ connecting them. In conventional circuit arrangements with capacitors disposed outside the coil, because of the greater length of the respective lines, relatively large ohmic losses result and thereby a low resonant circuit quality.

Accordingly, in arrangement 100 of the invention or in an LC resonant circuit realized hereby, an especially high resonant circuit quality results due to the short length for lines 112a′, 112a″.

Another advantageous effect, which results due to the reduced line length, is that circuit arrangement 100 has an overall lower noise level than conventional circuit arrangement with longer lines.

Furthermore, an increased noise immunity of circuit arrangement 100 results very advantageously due to the reduced area consumption according to the invention and the associated lower cross-sectional area of circuit arrangement 100.

Another embodiment of the present invention is shown in FIG. 2. In contrast to the embodiment according to FIG. 1, the coil of the embodiment shown in FIG. 2 has a circular conductor loop 110a instead of an octagonal conductor loop.

In principle, the coil of circuit arrangement 100 of the invention may also have conductor loops with any other forms, whereby a symmetric configuration of the coil is also preferred, however, to achieve the lowest possible magnetic field strength in interior region 115.

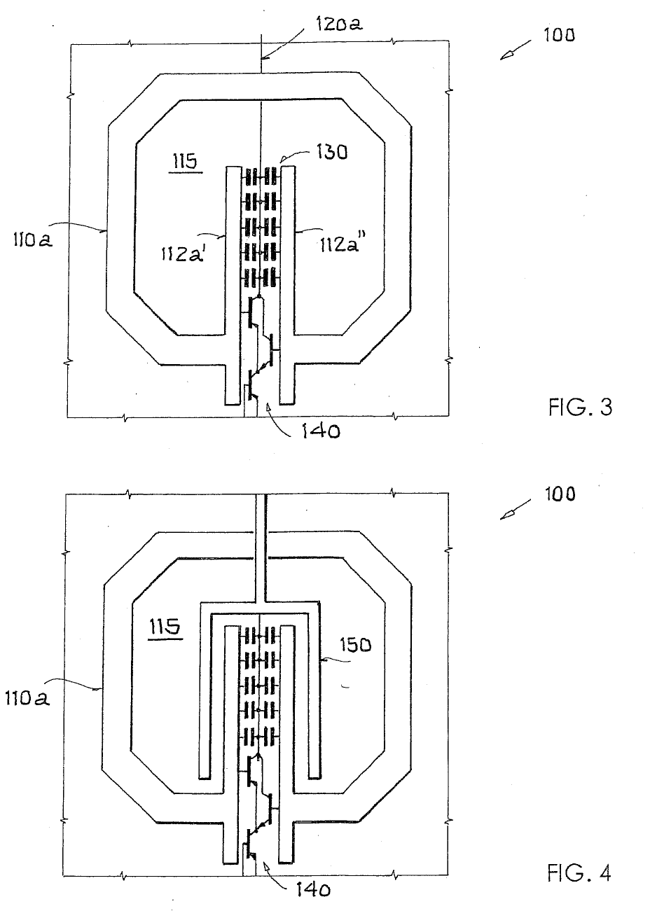

Another embodiment of the present invention is shown in FIG. 3. Circuit arrangement 100 according to FIG. 3 shows the arrangement according to the invention of a majority of capacitive elements formed as capacitors 130 and the arrangement of active elements formed as transistors 140 in the area of lines 112a′, 112a″ or in the area of the coil terminals.

During use of capacitors 130 with variably large capacitances, it is especially advantageous to arrange the capacitors with the greatest capacitance in the vicinity of active elements 140, and the capacitors with a lower capacitance at the end of lines 112a′, 112a″, said end facing away from active elements 140. This avoids that large currents, particularly during resonance operation, also flow unnecessarily through the ends of lines 112a′, 112a″, said ends lying at the top in FIG. 3, and thereby corresponding ohmic losses arise.

In another embodiment of the present invention, which is depicted schematically in FIG. 4, in the interior region 115 of the coil in addition a shielding device 150 is disposed, which assures extensive field freedom of the region of interior 115 surrounded by it. Shielding device 150 can be connected, for example, to a ground potential of circuit arrangement 100.

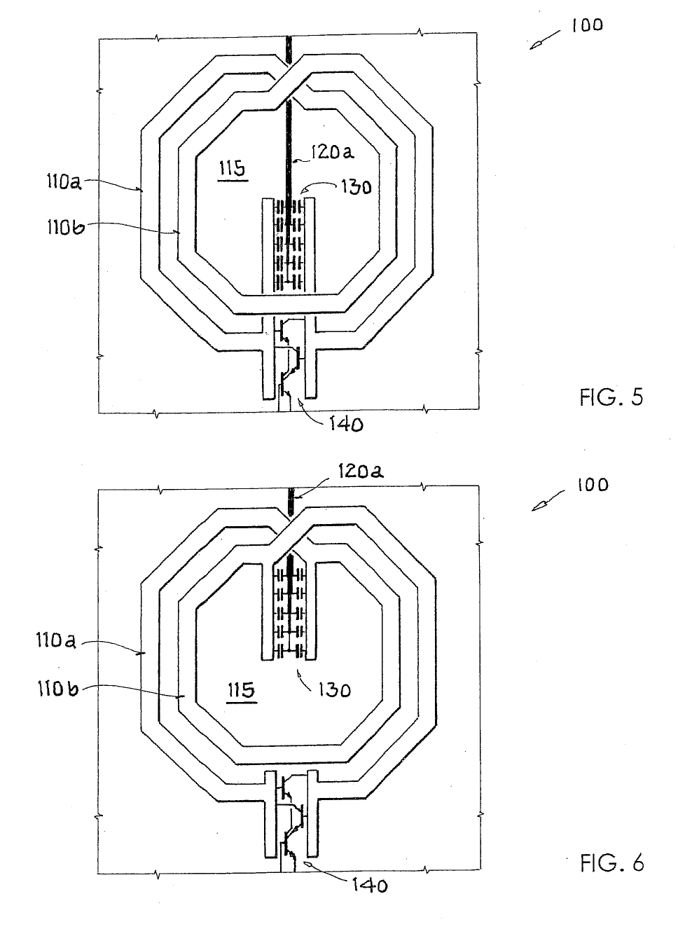

A circuit arrangement 100 with a coil having two turns is shown in each case in FIGS. 5 and 6, whereby capacitive elements 130 or one or more control lines 120a are again provided in an interior region 115 of the two conductor loops 110a, 110b.

In contrast to the configuration shown in FIG. 5, in the case of circuit arrangement 100 shown in FIG. 6, the configurable capacitor matrix consisting of capacitors 130 is connected to the interior conductor loop 110b of the coil, whereas transistors 140 are disposed as before in a terminal region of the coil.

This type of arrangement of capacitors 130 enables a complex influencing of the electrical properties of the coil, particularly for an adjustment of the coil inductance during use of circuit 100 of the invention in an LC resonant circuit or the like.

It is likewise possible to connect transistors 140 to the inner conductor loop 110b of the coil and to provide capacitors 130 in the terminal area of the coil, i.e., in the terminals of the outer conductor loop 110a.

Other embodiments of the present invention, particularly with a coil having more than two turns, are also conceivable, whereby such configurations are realized especially advantageously in a monolithic integrated circuit, which has several metallization levels.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A monolithic integrated circuit arrangement comprising:
a first circuit component that is formed as a differentially supplied coil and has at least one conductor loop encompassing an interior region; and
at least one additional circuit component being disposed in the interior region.

2. The circuit arrangement according to claim 1, wherein the additional circuit component has one or more passive elements, particularly capacitive elements.

3. The circuit arrangement according to claim 2, wherein the capacitive elements are formed as a configurable capacitor matrix and/or as capacitance diodes.

4. The circuit arrangement according to claim 1, wherein the additional circuit component has one or more active elements, particularly transistors.

5. The circuit arrangement according to claim 1, wherein different conductor sections of the differentially supplied coil, particularly different conductor loops of the coil, are disposed in different metallization levels of a substrate accommodating the circuit arrangement.

6. The circuit arrangement according to claim 1, further comprising a shielding device disposed in the interior region of the conductor loop and which extends at least partially between at least one conductor loop of the coil and the additional circuit component.

7. The circuit arrangement according to claim 1, wherein the coil has at least one pair of legs, each of which being symmetric to one another.

8. The circuit arrangement according to claim 7, wherein the additional circuit component and/or the control lines assigned to the additional circuit component are disposed in an area of and axis of symmetry of the coil, said axis running between the legs.

9. A monolithic integrated circuit having at least one circuit arrangement according to claim 1.

10. The circuit according to claim 9, wherein the integrated circuit includes at least two metallization levels.
